(19) United States
(12) Patent Application Publication
(10) Pub. No.: US 2026/0144134 A1
(43) Pub. Date: May 21, 2026

(54) Top Metal Layout Design Pattern to Improve Polyimide Film Adhesion for Passivated Devices

(71) Applicant: Microchip Technology Incorporated, Chandler, AZ (US)

(72) Inventors: Zhiming Feng, Milpitas, CA (US); Robin Haibing Liu, Fremont, CA (US); Xinyuan Dou, Fremont, CA (US); Moaniss Zitouni, Gilbert, AZ (US); William R. Lewis, Reading, PA (US); Pejman Khosropour, Campbell, CA (US); Eleonore Daemen, Trets (FR)

(21) Appl. No.: 19/308,153

(22) Filed: Aug. 22, 2025

Related U.S. Application Data
(60) Provisional application No. 63/723,274, filed on Nov. 21, 2024.

(51) Int. Cl. H01L 23/31; H01L 21/56; H01L 23/58

(52) U.S. Cl. CPC H10W 74/147; H10W 42/00; H10W 74/01

(57) ABSTRACT

A semiconductor device is provided. The semiconductor device may include a substrate, a circuit component disposed on the substrate, an oxide layer disposed on the circuit component, a top metal layer disposed on the oxide layer, a non-planarized passivation layer disposed on the top metal layer, and a polyimide layer disposed on the non-planarized passivation layer. The top metal layer may include a first default feature and a second default feature, and the non-planarized passivation layer may include one or more trenches between the first default feature and the second default feature.

### CROSS-REFERENCE TO RELATED APPLICATION

The present application claims priority to U.S. Provisional Patent Application No. 63/723,274, entitled: Top Metal Layout Design Pattern to Improve Polyimide Film Adhesion for Passivated Devices, filed on Nov. 21, 2024, the contents of which are hereby incorporated by reference in their entirety.

### TECHNICAL FIELD

The present disclosure relates generally to the field of semiconductor wafer

fabrication, and more specifically to a semiconductor device and a method for manufacturing a semiconductor device for improving the adhesion characteristics of polyimide films when applied to passivated devices.

### SUMMARY

According to an aspect of one or more examples, there is provided a semiconductor device. The semiconductor device may include a substrate, a circuit component disposed on the substrate, an oxide layer disposed on the circuit component, a top metal layer disposed on the oxide layer, a non-planarized passivation layer disposed on the top metal layer, and a polyimide layer disposed on the non-planarized passivation layer. The top metal layer may include a first default feature and a second default feature, and the non-planarized passivation layer may include one or more trenches between the first default feature and the second default feature. The top metal layer may include one or more metal features disposed near a periphery of the semiconductor device, and between the first default feature and the second default feature. The one or more metal features may be disposed at a corner region of the semiconductor device, and the one or more trenches may be formed by a passivation process that occurs after the one or more metal features are disposed. The one or more trenches may be among, between, or on the one or more metal features. The one or more trenches may include a first trench between the first default feature and a first metal feature of the one or more metal features, a second trench between the first metal feature and a second metal feature of the one or more metal features, and a third trench between the second metal feature and the second default feature, and a depth of the first trench may be shallower than a depth of the second trench, the depth of the second trench may be approximately equal to a depth of the third trench, and the depths of the first, second, and third trenches may be determined by a size of a respective opening in a mask. The one or more trenches may be formed or deepened by a photoresist process, the photoresist process comprising applying a mask on the passivation layer, the mask having openings that align with and correspond to the one or more trenches. The semiconductor device may also include one or more metal layers disposed between the oxide layer and the top metal layer.

According to an aspect of one or more examples, there is provided a semiconductor device. The semiconductor device may include a substrate, a circuit component disposed on the substrate, an oxide layer disposed on the circuit component, a top metal layer disposed on the oxide layer, a planarized passivation layer disposed on the top metal layer, and a polyimide layer disposed on the planarized passivation layer. The top metal layer may include a first default feature and a second default feature. The planarized passivation layer may include one or more trenches between the first default feature and the second default feature, and the one or more trenches may be formed by a photoresist process. The top metal layer may include one or more metal features disposed near a periphery of the semiconductor device, and between the first default feature and the second default feature. The one or more metal features may be disposed near a corner region of the semiconductor device. The one or more trenches may be among, between, or on the one or more metal features.

According to an aspect of one or more examples, there is provided a method of manufacturing a semiconductor device. The method may include depositing a top metal layer, depositing a passivation layer on the top metal layer, and depositing a polyimide layer on the passivation layer. The top metal layer may include a first default feature and a second default feature. The passivation layer may include one or more trenches between the first default feature and the second default feature. Depositing the top metal layer may include disposing one or more metal features near a periphery of the semiconductor device, and between the first default feature and the second default feature. The one or more metal features may be disposed in a corner region of the semiconductor device, and the one or more trenches may be formed by a passivation process that occurs after the one or more metal features are disposed. The method may also include applying a mask on the passivation layer, the mask including openings among or between the one or more metal features, and forming or deepening the one or more trenches in the passivation layer. The method may also include applying a mask on the passivation layer, the mask including openings on the one or more metal features, and forming the one or more trenches in the passivation layer. The method may also include planarizing the passivation layer. Depositing the top metal layer may include disposing one or more metal features at a periphery of the semiconductor device, and between the first default feature and the second default feature. The method may also include applying a mask on the passivation layer, the mask including openings on the one or more metal features, and forming the one or more trenches in the passivation layer. The method may also include applying a mask on the passivation layer, the mask including openings among or between the one or more metal features, and forming the one or more trenches in the passivation layer.

### BRIEF DESCRIPTION OF DRAWINGS

FIG. 1 shows a semiconductor device with a non-planarized passivation layer according one or more examples.

FIG. 2 shows a semiconductor device with a non-planarized passivation layer according to one or more examples.

FIG. 3 shows a semiconductor device with a non-planarized passivation layer according to one or more examples.

FIG. 4 shows a semiconductor device with a non-planarized passivation layer according to one or more examples.

FIGS. 5A-C show methods of manufacturing a semiconductor device according to FIGS. 1-4.

FIG. 6 shows a semiconductor device with a planarized passivation layer according to one or more examples.

FIG. 7 shows a semiconductor device with a planarized passivation layer according to one or more examples.

FIG. 8 shows a semiconductor device with a planarized passivation layer according to one or more examples.

FIGS. 9A and 9B show methods of manufacturing a semiconductor device according to FIGS. 6-8.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

In the wafer fabrication process, polyimide is extensively used as an insulating layer due to its thermal stability, electrical insulation properties, and chemical resistance. The effectiveness of polyimide in these applications depends at least in part on adhesion to ensure the reliability and longevity of the final semiconductor devices. The adhesion properties of polyimide materials are influenced by various factors, including the diversity in polyimide compositions, the specifics of the curing process, and the application of adhesion promoters. Additionally, mechanical and thermal stresses, particularly at the chip corners and edges, may affect adhesion performance. The thickness of the polyimide layer and the characteristics of the passivation process, such as whether a planarized passivation layer is used, further affect the adhesion dynamics.

One issue that arises in the wafer fabrication process is the potential for delamination of the polyimide, particularly at the corners and edges of the chip. This delamination is often caused by stress-induced failures, which can occur if these issues are not adequately addressed during circuit layout or wafer back-end processing stages. In particular, the risk of polyimide delamination may become pronounced if the passivation layer does not incorporate effective planarization, leading to weak adhesion at certain areas.

This issue may become particularly evident during the product development phase for analog and power semiconductor devices. Specifically, in the development of analog products, a problem of polyimide delamination or peeling at the chip corners and edges may occur. The adhesion of the polyimide film to the chip surface near the corners may be weaker compared to other areas, allowing for peeling from the chip surface and passivation layer. This adhesion issue has a detrimental impact on product yield and poses an obstacle to the release of new test chips for volume production. Addressing the problem of polyimide delamination may enhance the reliability and yield of semiconductor devices. Therefore, there may exist a need to improve the adhesion properties of polyimide, particularly at the chip corners and edges, to reduce the likelihood of delamination and improve the overall quality and performance of the final products.

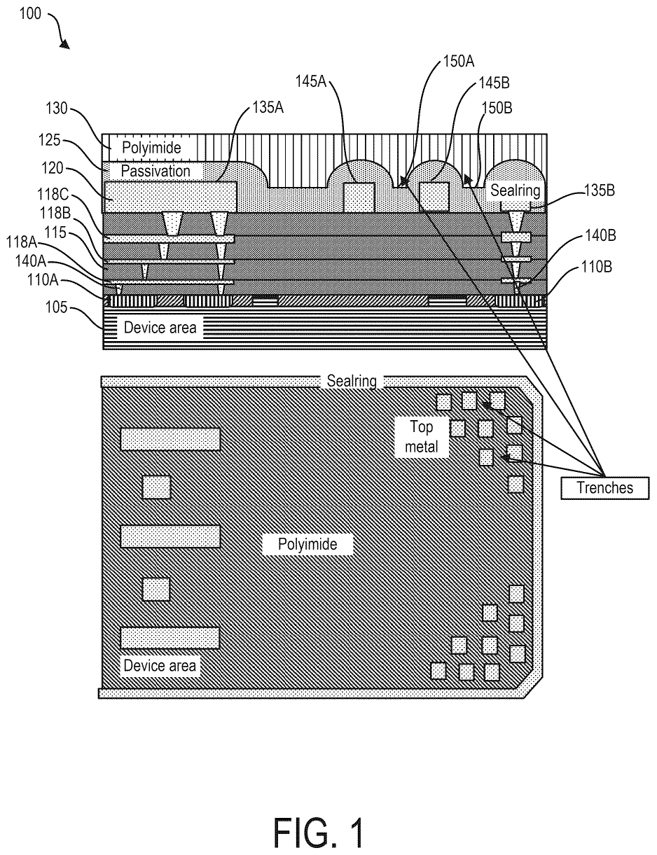

FIG. 1 shows a semiconductor device 100 with a non-planarized passivation layer according to one or more examples. Referring to FIG. 1, the semiconductor device 100 includes a substrate 105, circuit components 110A, 110B disposed on the substrate 105, an oxide layer 115 disposed on the circuit components 110A, 110B on the substrate 105, a top metal layer 120 disposed on the oxide layer 115, a non-planarized passivation layer 125 disposed on the top metal layer 120, and a polyimide layer 130 disposed on the non-planarized passivation layer 125. The substrate 105 may be composed of silicon (Si), silicon carbide (SiC), or any other suitable material. Circuit components 110A, 110B may be implanted on the substrate 105. Circuit components 110A, 110B may include, for example, transistors and resistors. The oxide layer 115 may be a layer of silicon dioxide (SiO₂), which may be formed by a thermal oxidation process of the substrate 105. The oxide layer 115 may be a layer of SiO₂, which may be formed or grown by a chemical vapor deposition (CVD) process of the substrate 105.

The top metal layer 120 may include a first default feature 135A and a second default feature 135B. The first default feature 135A may be coupled to a first circuit component 110A on the substrate 105 via a first interconnect 140A in the oxide layer 115, and the second default 135B feature may be coupled to a second circuit component 110B on the substrate 105 via a second interconnect 140B in the oxide layer 115. The second default feature 135B may be located along an outer perimeter of the semiconductor device 100. One or more metal layers may be disposed between one or more oxide layers 115 and the top metal layer 120. As shown in FIG. 1, three metal layers 118A, 118B, 118C may be disposed between a corresponding oxide layer 115 and the top metal layer 120. According to one or more examples, the top metal layer 120 may include one or more metal features 145A, 145B disposed at a periphery of the semiconductor device 100, and between the first default feature 135A and the second default feature 135B. According to one or more examples, the one or more metal features 145A, 145B may be disposed at a corner region of the semiconductor device 100. The top metal layer 120 may include one or more metal features 145A, 145B between the first default feature 135A and the second default feature 135B. In various examples, the one or more metal features 145A, 145B may be rectangular or variously shaped. In various examples, a dimension of the one or more metal features 145A, 145B may be adjusted. Spacing between the one or more metal features 145A, 145B may be approximately 5 micrometers to 15 micrometers, less than 5 micrometers, or greater than 15 micrometers.

The non-planarized passivation layer 125 may include one or more trenches 150A, 150B between the first default feature 135A and the second default feature 135B. The one or more trenches 150A, 150B may be formed by a passivation process that occurs after the one or more metal features 145A, 145B are disposed. In addition to trenches 150A, 150B, one or more trenches may be formed between the first default feature 135A and the first metal feature 145A.

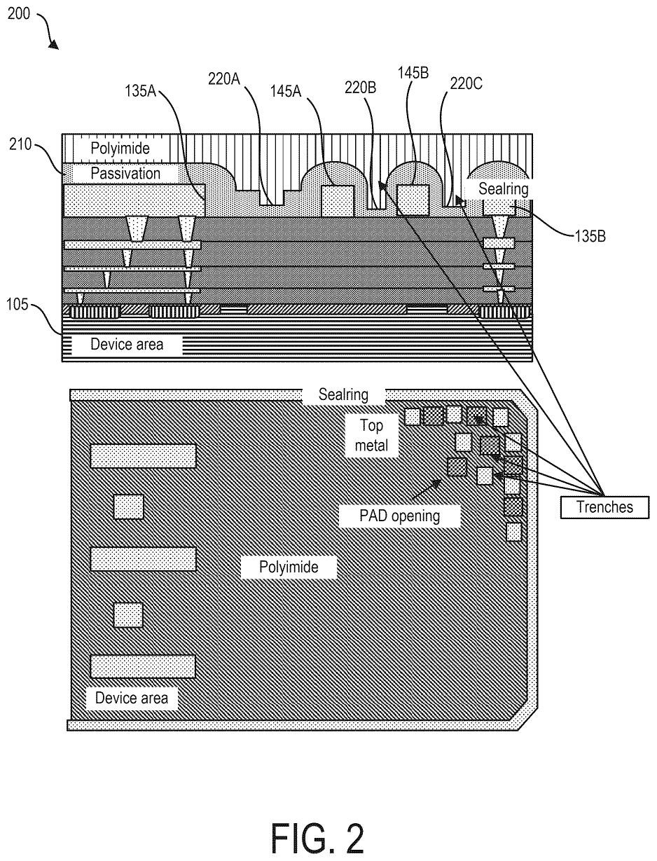

FIG. 2 shows a semiconductor device 200 with a non-planarized passivation layer according to one or more examples. Referring to FIG. 2, the one or more trenches 220A, 220B, 220C may be formed or deepened by a photoresist process. The photoresist process may include applying a mask on the non-planarized passivation layer 210, the mask having openings among or between the one or more metal features 145A, 145B, and forming the one or more trenches 220A, 220B, 220C in the non-planarized passivation layer 210. In various examples, depths of the one or more trenches 220A, 220B, 220C may be less than a thickness of the passivation layer 210. For example, as shown in FIG. 2, a depth of a first trench 220A may be shallower than a depth of a second trench 220B, and the depth of the second trench 220B may be approximately equal to a depth of a third trench 220C. Depths of the one or more trenches 220A, 220B, 220C may be determined by sizes of the openings in the mask applied on the passivation layer 210.

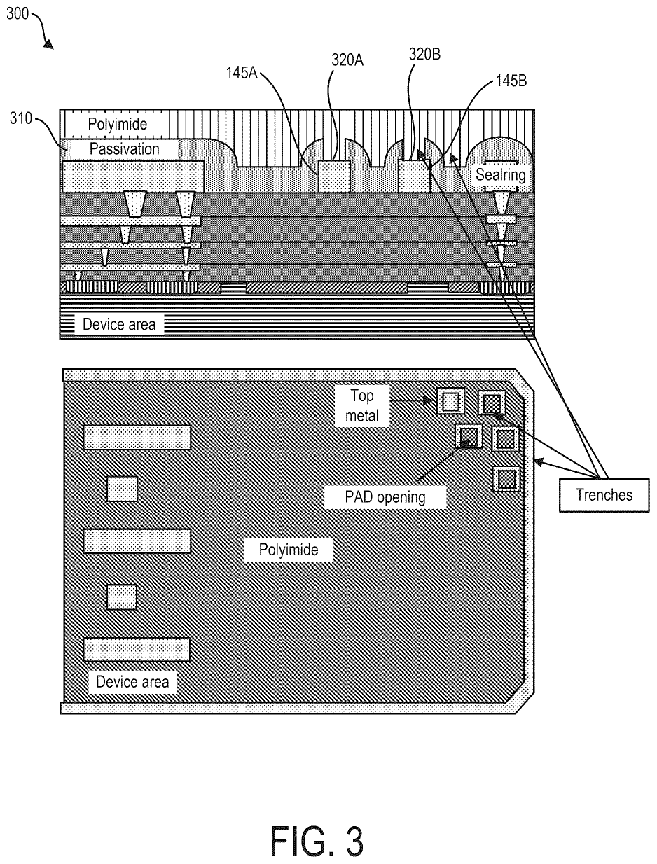

FIG. 3 shows a semiconductor device 300 with a non-planarized passivation layer according one or more examples. Referring to FIG. 3, the one or more trenches 320A, 320B may be formed by a photoresist process. The photoresist process may include applying a mask on the non-planarized passivation layer 310, the mask having openings on the one or more metal features 145A, 145B, and forming the one or more trenches 320A, 320B in the non-planarized passivation layer 310. In addition to trenches 320A, 320B, one or more trenches may be formed among or between the one or more metal features 145A, 145B, similar to FIG. 2.

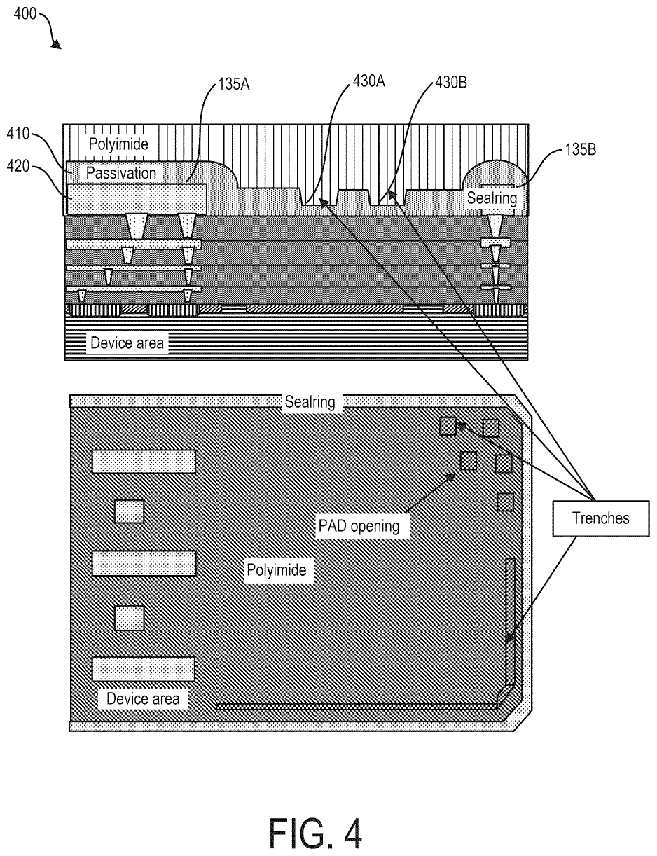

FIG. 4 shows a semiconductor device 400 with a non-planarized passivation layer according to one or more examples. Referring to FIG. 4, the one or more trenches 430A, 430B may be formed by a photoresist process. The photoresist process may include applying a mask on the non-planarized passivation layer 410, the mask having openings between the first default feature 135A and the second default feature 135B, and forming the one or more trenches 430A, 430B in the non-planarized passivation layer 410. The one or more trenches 430A, 430B may be approximately equal in width, height, depth, or any combination thereof. In addition to trenches 430A, 430B, one or more trenches may be formed at a periphery of the semiconductor device 400.

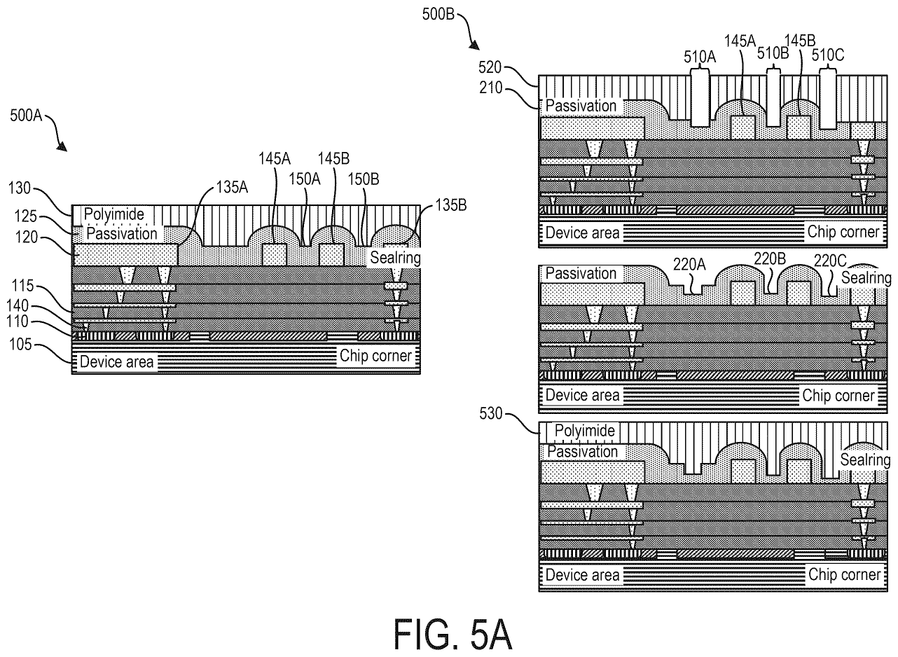

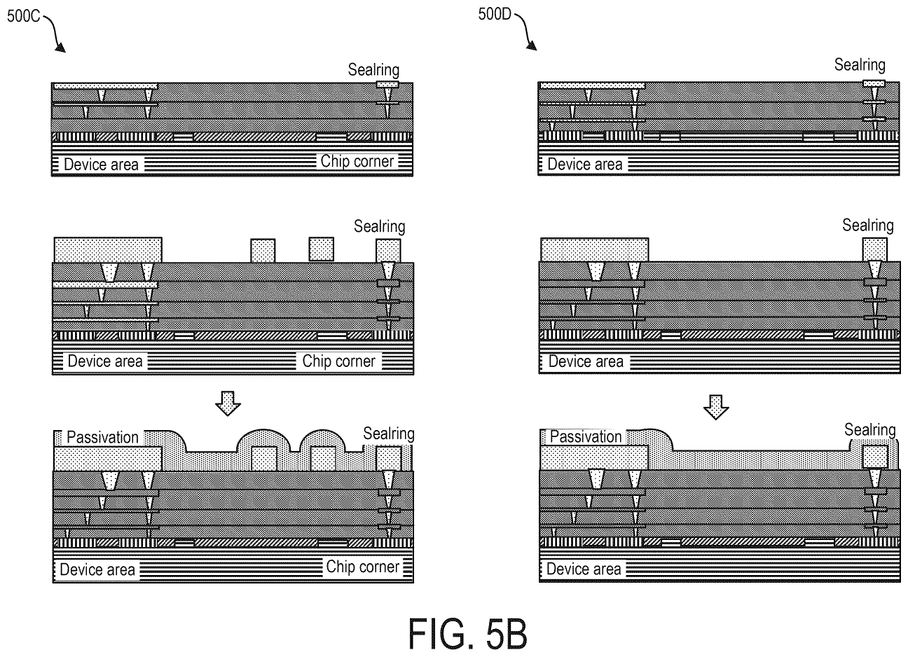

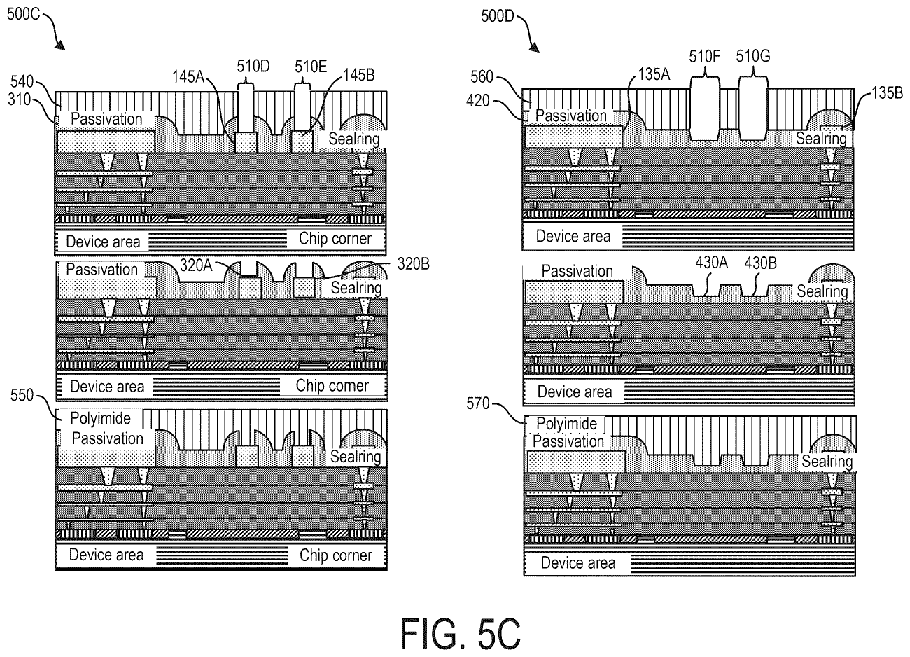

FIGS. 5A-C show methods 500A, 500B, 500C, 500D of manufacturing a semiconductor device according to FIGS. 1-4, respectively. The methods 500A, 500B, 500C, 500D of manufacturing a semiconductor device (e.g., semiconductor device 100, 200, 300, 400) may include depositing a top metal layer 120, depositing a passivation layer (e.g., passivation layer 125, 210, 310, 420) on the top metal layer 120, and depositing a polyimide layer 130 on the passivation layer. The layers of various materials may be deposited on the substrate 105 using techniques such as chemical vapor deposition (CVD) and physical vapor deposition (PVD). The top metal layer 120 may include a first default feature 135A and a second default feature 135B. The passivation layer may include one or more trenches (e.g., trenches 145A, 145B, 220A, 220B, 220C, 320A, 320B, 430A, 430B) between the first default feature 135A and the second default feature 135B. According to one or more examples, depositing the top metal layer 120 may include disposing one or more metal features 145A, 145B at a periphery of the semiconductor device 100, and between the first default feature 135A and the second default feature 135B.

As shown in FIG. 5A, the method 500A of manufacturing a semiconductor device (e.g., semiconductor device 100) may include disposing the one or more metal features 145A, 145B in a corner region of the semiconductor device, and the one or more trenches 150A, 150B may be formed by a passivation process that occurs after the one or more metal features 145A, 145B are disposed. The polyimide layer 130 may then be deposited on the non-planarized passivation layer 125.

As shown in FIG. 5A, the method 500B of manufacturing a semiconductor device (e.g., semiconductor device 200) may include applying a mask 520 on the non-planarized passivation layer 210, the mask 520 including openings 510A, 510B, 510C among or between the one or more metal features 145A, 145B, and forming or deepening the one or more trenches 220A, 220B, 220C in the non-planarized passivation layer 210. For example, a first trench 220A is to the left of the first metal feature 145A, a second trench 220B is between the first metal feature 145A and the second metal feature 145B, and a third trench 220C is to the right of the second metal feature 145B. The mask 520 may be applied on the non-planarized passivation layer 210 by a photoresist process. The polyimide layer 530 may then be deposited on the non-planarized passivation layer 210.

As shown in FIGS. 5B and 5C, the method 500C of manufacturing a semiconductor device (e.g., semiconductor device 300) may include applying a mask 540 on the non-planarized passivation layer 310, the mask 540 including openings 510D, 510E on the one or more metal features 145A, 145B, and forming the one or more trenches 320A, 320B in the non-planarized passivation layer 310. The mask 540 may be applied on the non-planarized passivation layer 310 by a photoresist process. The polyimide layer 550 may then be deposited on the non-planarized passivation layer 310.

According to one or more examples, the method 500D of manufacturing a semiconductor device (e.g., semiconductor device 400) may include applying a mask 560 on the non-planarized passivation layer 420, the mask 560 including openings 510F, 510G between the first default feature 135A and the second default feature 135B, and forming the one or more trenches 430A, 430B in the non-planarized passivation layer 420.. The mask 560 may be applied on the non-planarized passivation layer 420 by a photoresist process. The polyimide layer 570 may then be deposited on the non-planarized passivation layer 420.

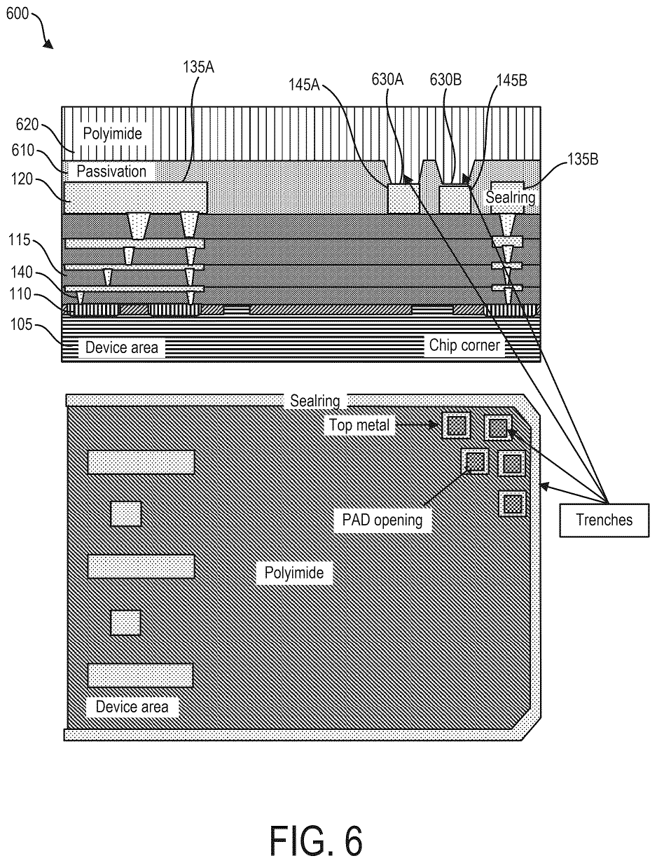

FIG. 6 shows a semiconductor device 600 with a planarized passivation layer according to one or more examples. Referring to FIG. 6, the semiconductor device 600 may include a substrate 105, a circuit component 110 disposed on the substrate 105, an oxide layer 115 disposed on the circuit component 110 on the substrate 105, a top metal layer 120 disposed on the oxide layer 115, a planarized passivation layer 610 disposed on the top metal layer 120, and a polyimide layer 620 disposed on the planarized passivation layer 610. The planarized passivation layer 610 may include one or more trenches 630A, 630B between the first default feature 135A and the second default feature 135B. The top metal layer 120 may include one or more metal features 145A, 145B disposed at a periphery of the semiconductor device 600, and between the first default feature 135A and the second default feature 135B. The one or more metal features 145A, 145B may be disposed at a corner region of the semiconductor device 600. The one or more trenches 630A, 630B may be formed by a photoresist process. The photoresist process may include applying a mask on the planarized passivation layer 610, the mask including openings on the one or more metal features 145A, 145B, and forming the one or more trenches 630A, 630B in the planarized passivation layer 610.

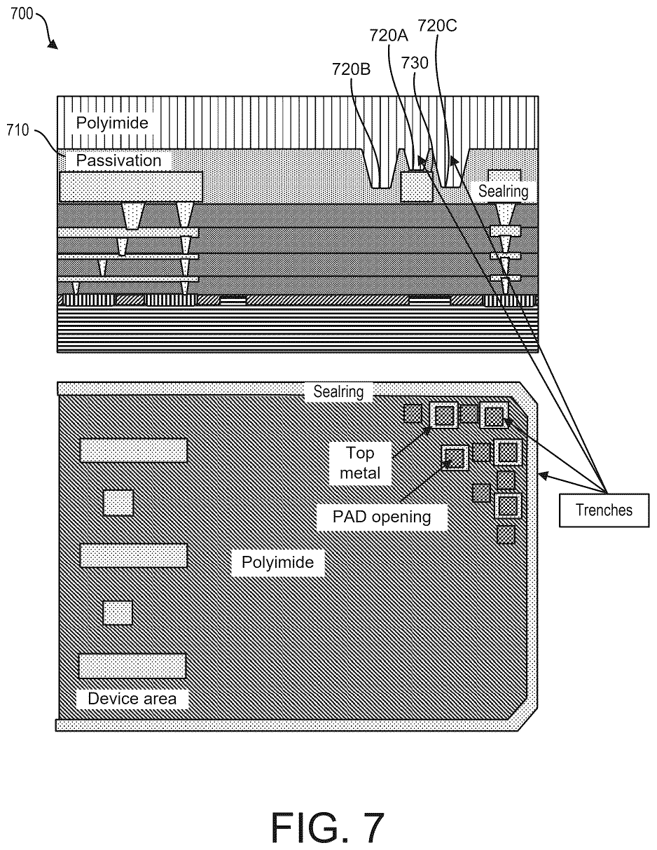

FIG. 7 shows a semiconductor device 700 with a planarized passivation layer according to one or more examples. Referring to FIG. 7, the one or more trenches 720A, 720B, 720C may be formed by a photoresist process. The photoresist process may include applying a mask on the planarized passivation layer 710, the mask including openings among, between, and on the one or more metal features 730, and forming the one or more trenches 720A, 720B, 720C in the planarized passivation layer 710. For example, trench 720A may be on the metal feature 730, and trenches 720B, 720C may be among and between the metal feature 730.

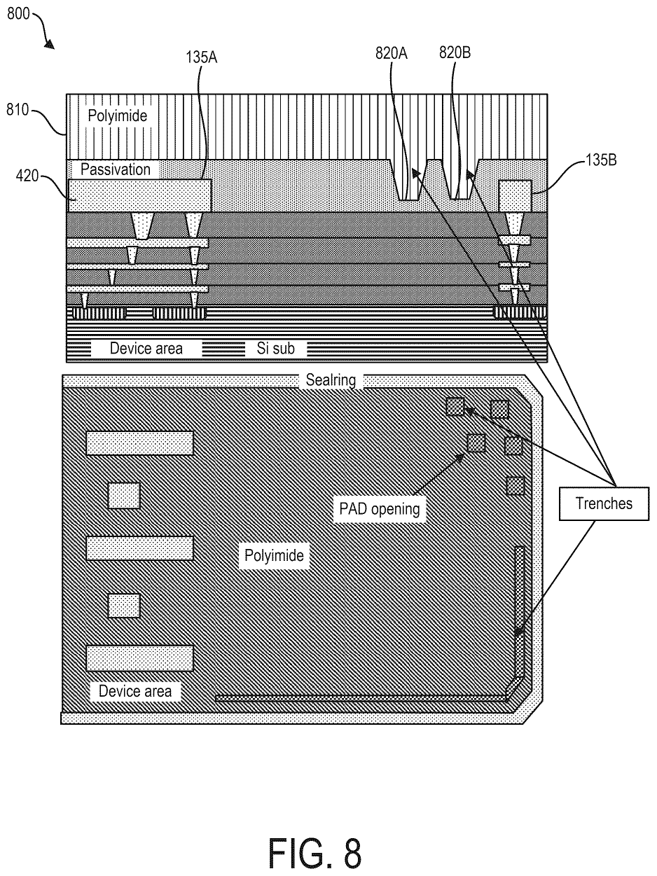

FIG. 8 shows a semiconductor device 800 with a planarized passivation layer according to one or more examples. Referring to FIG. 8, the one or more trenches 820A, 820B may be formed by a photoresist process. The photoresist process may include applying a mask on the planarized passivation layer 810, the mask including openings between the first default feature 135A and the second default feature 135B, and forming the one or more trenches 820A, 820B in the planarized passivation layer 810. In addition to trenches 820A, 820B, one or more trenches may be formed at a periphery of the semiconductor device 800.

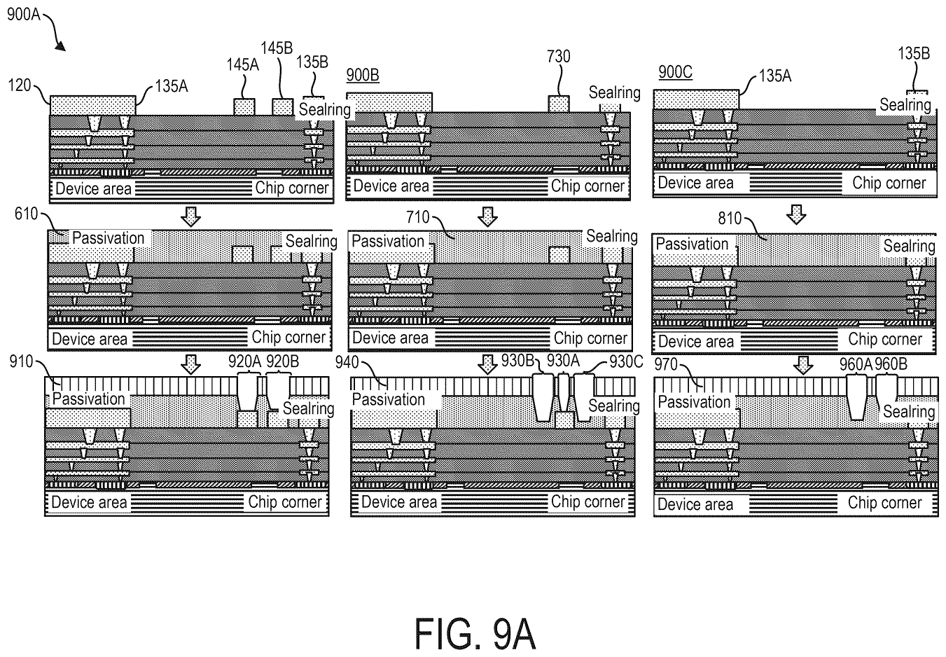

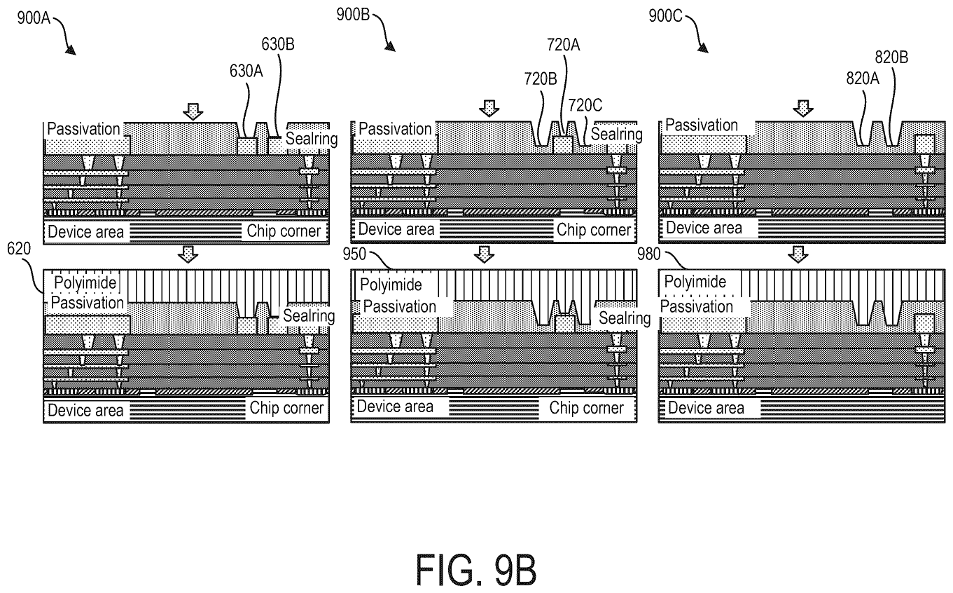

FIGS. 9A and 9B show methods 900A, 900B, 900C of manufacturing a semiconductor device according to FIGS. 6-8, respectively. The methods 900A, 900B, 900C of manufacturing a semiconductor device (e.g., semiconductor device 600, 700, 800) may include depositing a top metal layer 120, depositing a passivation layer (e.g., passivation layer 610, 710, 810) on the top metal layer 120, and depositing a polyimide layer (e.g., polyimide layer 620, 950, 980) on the passivation layer. The top metal layer 120 may include a first default feature 135A and a second default feature 135B. The passivation layer may include one or more trenches between the first default feature 135A and the second default feature 135B. According to one or more examples, the method may also include planarizing the passivation layer. According to one or more examples, depositing the top metal layer 120 may include disposing one or more metal features 145A, 145B at a periphery of the semiconductor device, and between the first default feature 135A and the second default feature 135B.

As shown in FIGS. 9A and 9B, the method 900A may include applying a mask 910 on the passivation layer 610, the mask 910 including openings 920A, 920B on the one or more metal features 145A, 145B, and forming the one or more trenches 630A, 630B in the passivation layer 610. The mask 910 may be applied on the planarized passivation layer 610 by a photoresist process. The polyimide layer 620 may then be deposited on the planarized passivation layer 610.

As shown in FIGS. 9A and 9B, the method 900B of manufacturing a semiconductor device (e.g., semiconductor device 700) may include applying a mask 940 on the passivation layer 710, the mask 940 including openings 930A, 930B, 930C among, between, and on the one or more metal features 730, and forming the one or more trenches 720A, 720B, 720C in the passivation layer 710. The mask 940 may be applied on the planarized passivation layer 710 by a photoresist process. The polyimide layer 950 may then be deposited on the planarized passivation layer 710.

As shown in FIGS. 9A and 9B, the method 900C of manufacturing a semiconductor device (e.g., semiconductor device 800) may not include disposing one or more metal features (e.g., metal features 145A, 145B) at a periphery of the semiconductor device, and between the first default feature 135A and the second default feature 135B. The method 900C may include applying a mask 970 on the passivation layer 810, the mask 970 including openings 960A, 960B between the first default feature 135A and the second default feature 135B, and forming the one or more trenches 820A, 820B in the passivation layer 810. The mask 970 may be applied on the planarized passivation layer 810 by a photoresist process. The polyimide layer 980 may then be deposited on the planarized passivation layer 810.

Various examples have been disclosed herein, in connection with the above description and the drawings. It will be understood that it would be unduly repetitious to literally describe and illustrate every combination and subcombination of these examples. Accordingly, all examples can be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A semiconductor device comprising:
a substrate;
a circuit component disposed on the substrate;
an oxide layer disposed on the circuit component;
a top metal layer disposed on the oxide layer;
a non-planarized passivation layer disposed on the top metal layer; and
a polyimide layer disposed on the non-planarized passivation layer,
wherein the top metal layer comprises a first default feature and a second default feature, and
wherein the non-planarized passivation layer comprises one or more trenches between the first default feature and the second default feature.

2. The semiconductor device of claim 1, wherein the top metal layer comprises one or more metal features disposed near a periphery of the semiconductor device, and between the first default feature and the second default feature.

3. The semiconductor device of claim 2, wherein the one or more metal features are disposed at a corner region of the semiconductor device, and
wherein the one or more trenches are formed by a passivation process that occurs after the one or more metal features are disposed.

4. The semiconductor device of claim 2, wherein the one or more trenches are among, between, or on the one or more metal features.

5. The semiconductor device of claim 2, wherein the one or more trenches comprise a first trench between the first default feature and a first metal feature of the one or more metal features, a second trench between the first metal feature and a second metal feature of the one or more metal features, and a third trench between the second metal feature and the second default feature; and
wherein a depth of the first trench is shallower than a depth of the second trench, the depth of the second trench is approximately equal to a depth of the third trench, and the depths of the first, second, and third trenches are determined by a size of a respective opening in a mask.

6. The semiconductor device of claim 1, wherein the one or more trenches are formed or deepened by a photoresist process, the photoresist process comprising applying a mask on the passivation layer, the mask having openings that align with and correspond to the one or more trenches.

7. The semiconductor device of claim 1, comprising one or more metal layers disposed between the oxide layer and the top metal layer.

8. A semiconductor device comprising:
a substrate;
a circuit component disposed on the substrate;
an oxide layer disposed on the circuit component;
a top metal layer disposed on the oxide layer;
a planarized passivation layer disposed on the top metal layer; and
a polyimide layer disposed on the planarized passivation layer,
wherein the top metal layer comprises a first default feature and a second default feature, and
wherein the planarized passivation layer comprises one or more trenches between the first default feature and the second default feature, and the one or more trenches are formed by a photoresist process.

9. The semiconductor device of claim 8, wherein the top metal layer comprises one or more metal features disposed near a periphery of the semiconductor device, and between the first default feature and the second default feature.

10. The semiconductor device of claim 8, wherein the one or more metal features are disposed near a corner region of the semiconductor device.

11. The semiconductor device of claim 9, wherein the one or more trenches are among, between, or on the one or more metal features.

12. A method of manufacturing a semiconductor device, the method comprising:
depositing a top metal layer;
depositing a passivation layer on the top metal layer; and
depositing a polyimide layer on the passivation layer,
wherein the top metal layer comprises a first default feature and a second default feature, and
wherein the passivation layer comprises one or more trenches between the first default feature and the second default feature.

13. The method of claim 12, wherein depositing the top metal layer comprises disposing one or more metal features near a periphery of the semiconductor device, and between the first default feature and the second default feature.

14. The method of claim 13, wherein the one or more metal features are disposed in a corner region of the semiconductor device, and
wherein the one or more trenches are formed by a passivation process that occurs after the one or more metal features are disposed.

15. The method of claim 13, further comprising:
applying a mask on the passivation layer, the mask including openings among or between the one or more metal features;
forming or deepening the one or more trenches in the passivation layer.

16. The method of claim 13, further comprising:
applying a mask on the passivation layer, the mask including openings on the one or more metal features;
forming the one or more trenches in the passivation layer.

17. The method of claim 12, further comprising:
planarizing the passivation layer.

18. The method of claim 17, wherein depositing the top metal layer comprises disposing one or more metal features at a periphery of the semiconductor device, and between the first default feature and the second default feature.

19. The method of claim 18, further comprising:
applying a mask on the passivation layer, the mask including openings on the one or more metal features;
forming the one or more trenches in the passivation layer.

20. The method of claim 18, further comprising:
applying a mask on the passivation layer, the mask including openings among or between the one or more metal features;
forming the one or more trenches in the passivation layer.
